(19) United States
(12) Patent Application Publication
(10) Pub. No.: US 2026/0297410 A1
(43) Pub. Date: Oct. 1, 2026

(54) Additives for Thermal Management Fluid and Thermal Management Fluid Compositions Including Same

(71) Applicants: SK Innovation Co., Ltd., Seoul (KR); SK On Co., Ltd., Seoul (KR)

(72) Inventors: Kang Min JUNG, Daejeon (KR); Hak Mook KIM, Daejeon (KR); Ki Wan KIM, Daejeon (KR); Sang Hye SHIN, Daejeon (KR); Hong Won LEE, Daejeon (KR); Dong Gun LEE, Daejeon (KR); Jung A LEE, Daejeon (KR)

(21) Appl. No.: 19/576,213

(22) Filed: Mar. 24, 2026

(30) Foreign Application Priority Data
Mar. 25, 2025 (KR) 10-2025-0038279
Mar. 19, 2026 (KR) 10-2026-0049566

(51) Int. Cl. C09K 5/10; C07F 9/09; C09K 21/12; H05K 7/20

(52) U.S. Cl. CPC C09K 5/10; C07F 9/09; C09K 21/12; H05K 7/20236

(57) ABSTRACT

A phosphorus-based additive composition for a thermal management fluid, the phosphorus-based additive composition comprising a first phosphorus-based additive and a second phosphorus-based additive, in which the second phosphorus-based additive has a greater molecular weight than the first phosphorus-based additive. A thermal management fluid composition comprising the phosphorus-based additive composition.

### CROSS REFERENCE TO RELATED APPLICATIONS

The present application claims priority to Korean Patent Application Nos. 10-2025-0038279, filed Mar. 25, 2025, and 10-2026-0049566, filed Mar. 19, 2026, the entire contents of which are incorporated herein by this reference.

### BACKGROUND

### Field

The present disclosure relates to a phosphorus-based additive composition for a thermal management fluid and to a thermal management fluid composition including the same.

### Description of Related Art

Thermal management fluids refer to fluids designed to efficiently transfer and regulate thermal energy, and are primarily employed in cooling and heating systems.

A coolant functions to absorb heat generated from a heat source, thereby reducing the temperature of the heat source. Desirable properties of a coolant include high thermal efficiency, low viscosity, low cost, non-toxicity, chemical stability, and non-corrosiveness toward system components.

As electronic products such as electric vehicles continue to achieve higher performance levels, an increasing amount of heat is generated during their operation. To ensure reliable operation and to prevent a reduction in product lifespan, effective thermal control of heat generated within such products has become an essential consideration.

Immersion cooling is one of the cooling methods used for thermal management of electronic devices and computer systems. In immersion cooling, electronic devices are cooled through direct contact with a fluid, which enables more effective heat removal compared to conventional air-cooling or water-cooling methods.

Meanwhile, higher capacity batteries in modern electronic products face increased thermal runaway risks, causing battery fires. In an immersion cooling system, a thermal management fluid cools a battery by fully submerging the battery in the thermal management fluid, which isolates the battery from atmospheric oxygen and suppresses battery fires to a certain extent by creating an oxygen-deprived environment.

The foregoing is intended merely to aid in the understanding of the background of the present disclosure, and is not intended to mean that the present disclosure falls within the purview of the related art that is already known to those skilled in the art.

### SUMMARY

According to one aspect of the present disclosure, provided herein is a phosphorus-based additive composition capable of improving fire propagation prevention performance of a thermal management fluid.

According to another aspect of the present disclosure, provided herein is a thermal management fluid composition comprising the phosphorus-based additive composition.

A phosphorus-based additive composition for a thermal management fluid according to one aspect of the present disclosure may comprise: a first phosphorus-based additive; and a second phosphorus-based additive. In certain embodiments, the second phosphorus-based additive may have a greater molecular weight than the first phosphorus-based additive.

According to one embodiment, the first phosphorus-based additive may have a molecular weight of about 100 g/mol to less than about 300 g/mol.

According to one embodiment, the first phosphorus-based additive may include a compound represented by Chemical Formula 1 below:

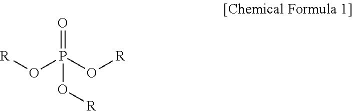

In Chemical Formula 1, each R may independently be hydrogen or a functional group having 1 to 14 carbon atoms, at least one R may not be hydrogen, and a total number of carbon atoms in the compound of Chemical Formula 1 may be 1 to 14.

According to one embodiment, the second phosphorus-based additive may have a molecular weight of about 100 g/mol to about 500 g/mol.

According to one embodiment, the second phosphorus-based additive may include a compound represented by Chemical Formula 2 below:

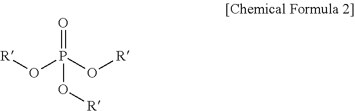

In Chemical Formula 2, each R′ may independently be hydrogen or a functional group having 1 to 30 carbon atoms, at least one R′ may not be hydrogen, and a total number of carbon atoms in the compound of Chemical Formula 2 may be 1 to 30.

According to one embodiment, the weight ratio of the first phosphorus-based additive to the second phosphorus-based additive may be about 1:3 to about 3:1.

According to one embodiment, the phosphorus-based additive composition, when added to a thermal management fluid, may increase the flash point of the thermal management fluid by at least about 10° C.

A thermal management fluid composition according to another aspect of the present disclosure may comprise: a base oil; and a phosphorus-based additive.

According to one embodiment, the thermal management fluid composition may comprise: about 90 wt % to about 98 wt % of the base oil; and equal to or less than about 8 wt % of the phosphorus-based additive.

According to one embodiment, the base oil may include mineral oil, synthetic oil, vegetable oil, or any combination thereof.

According to one embodiment, the phosphorus-based additive may comprise: a first phosphorus-based additive having a molecular weight of about 100 g/mol to less than about 300 g/mol; and a second phosphorus-based additive having a molecular weight of about 100 g/mol to about 500 g/mol.

According to one embodiment, the thermal management fluid composition may further comprise a second additive. Non-limiting examples of suitable second additives include an antioxidant, an anti-foaming agent, a corrosion inhibitor, a detergent, a dispersant, a friction modifier, an anti-wear agent, an extreme-pressure additive, a viscosity index improver, a pour-point depressant, a viscosity modifier, and any combination thereof.

According to one embodiment, the thermal management fluid composition may have a flash point of at least 200° C.

In one embodiment, the first phosphorus-based additive comprises triethyl phosphate. In one embodiment, the second phosphorus-based additive comprises tris(2-ethylhexyl) phosphate.

Also provided herein is a method of improving fire propagation prevention in a thermal management fluid, comprising adding the phosphorus-based additive composition according to any embodiment disclosed herein (e.g., a phosphorus-based additive composition comprising a first and second phosphorus-based additive) to the thermal management fluid.

Also provided herein is a method of immersion cooling an electronic device, comprising contacting the device with the thermal management fluid composition according to any embodiment disclosed herein (e.g., comprising a base oil and a phosphorus-based additive composition).

Also provided herein is a method of increasing the flash point of a thermal management fluid by at least about 10° C., comprising adding a phosphorus-based additive composition according to any embodiment disclosed herein (e.g., the phosphorus-based additive composition) to the thermal management fluid.

According to one embodiment, application of the phosphorus-based additives can improve fire propagation prevention performance of a thermal management fluid.

According to one embodiment, the phosphorus-based additives can effectively maintain functionality even under high-temperature conditions such as thermal runaway.

According to one embodiment, application of the additives can enhance the flash point of a thermal management fluid.

According to one embodiment, a thermal management fluid to which the additives are applied can be used as an immersion-cooling fluid.

### DETAILED DESCRIPTION

Hereinafter, the present disclosure will be described in detail. However, the following description is merely illustrative, and the present disclosure is not limited to the specific embodiments exemplarily described herein.

### Phosphorus-Based Additive Composition for Thermal Management Fluid

One aspect of the present disclosure provides a phosphorus-based additive composition for a thermal management fluid. The phosphorus-based additive composition comprises a first phosphorus-based additive and a second phosphorus-based additive. In certain embodiments, the second phosphorus-based additive has a greater molecular weight than the first phosphorus-based additive. As used herein, the term “phosphorus-based additive” refers to an additive comprising a compound containing the element phosphorus (P).

The phosphorus-based additive composition may be added to a thermal management fluid. The phosphorus-based additive composition may be incorporated to suppress the propagation of fire from a nearby electronic product (e.g., a battery) to other products, components, or surrounding areas in the event of a fire. In certain embodiments, the phosphorus-based additive composition may enhance the chemical fire suppression capability of the thermal management fluid. For example, during thermal runaway of a battery, the ambient temperature may rapidly increase to a temperature of 1,000° C. or higher. Under such extreme thermal conditions, the phosphorus-based additive composition of the present disclosure may prevent the propagation of fire to adjacent battery cells, thereby minimizing damage caused by battery thermal runaway.

Combustion of a material proceeds through chain reactions in which free radicals are continuously generated and consumed. During combustion, the phosphorus-based additive decomposes to generate radicals that function to remove surrounding free radicals. In other words, the phosphorus-based additive may contribute to preventing fire propagation by interrupting the chain reactions through scavenging highly reactive free radicals generated during thermal decomposition at high temperatures.

The phosphorus-based additive composition also increases the flash point of a thermal management fluid, in certain embodiments, by at least about 10° C. This improvement is attributed to radicals generated through thermal decomposition of the additives scavenging highly reactive radicals that would otherwise form from the base oil.

Further, the phosphorus-based additives effectively maintain functionality even under high-temperature conditions such as thermal runaway. By employing two additives with different molecular weights, and thus different decomposition temperatures, the composition provides flame-retardant performance across a broader temperature range (approximately 200° C. for the first additive and approximately 400° C. for the second).

When used in immersion cooling systems, the thermal management fluid composition provides both physical fire suppression (oxygen deprivation) and chemical fire suppression. Experimental testing demonstrated that use of the additives not only prevented fire propagation beyond an insulation layer but also effectively suppressed heating of adjacent battery cells (reducing adjacent cell temperatures from 158° C. to as low as 98° C.).

As described above, the phosphorus-based additive composition comprises a first phosphorus-based additive and a second phosphorus-based additive, wherein the second phosphorus-based additive has a greater molecular weight than the first phosphorus-based additive. In certain embodiments, the molecular weight of the first phosphorus-based additive may be less than about 300 g/mol. For example, the molecular weight of the first phosphorus-based additive may be about 100 g/mol to less than about 300 g/mol, about 100 to about 250 g/mol, about 100 to about 200 g/mol, or about 150 to about 200 g/mol. The first phosphorus-based additive (or the second phosphorus-based additive) may be a small molecule (or a monomeric compound), an oligomer, or a polymer. Specifically, it may be a small molecule. When the additive is a small molecule, the molecular weight refers to a value calculated from the chemical formula. In the case of an oligomer or a polymer, the molecular weight refers to a weight average molecular weight. Additionally, for the oligomer or the polymer, the weight average molecular weight refers to a polystyrene-equivalent molecular weight measured by gel permeation chromatography (GPC).

According to another embodiment, the decomposition temperature of the first phosphorus-based additive may be about 150° C. to about 250° C., about 170° C. to about 230° C., about 180° C. to about 220° C., or about 200° C. Decomposition temperature of the additive may be measured by methods known in the art, for example, thermogravimetric analysis (TGA) per ASTME1131 or ISO 11358. When the ambient temperature reaches the decomposition temperature, the first phosphorus-based additive may undergo thermal decomposition and perform a flame-retardant function. However, when the molecular weight of the first phosphorus-based additive exceeds the above-described range, the flame-retardant performance at about 200° C. may degrade.

As used herein, the term “about” refers to a value within 1% of the recited value. When used with respect to temperature “about” refers to a temperature within 1 degrees of the recited temperature.

In one embodiment, the first phosphorus-based additive may comprise a phosphate-based compound. As used herein, the term “phosphate-based compound” refers to a compound containing phosphate. In certain embodiments, the phosphate-based compound may be an organic phosphate compound. According to one embodiment, the first phosphorus-based additive may be or consist of one or more phosphate-based compounds. According to another embodiment, the first phosphorus-based additive may comprise at least one phosphate-based compound but optionally also other phosphorus-based compounds.

In embodiments in which the first phosphorus-based additive comprises a phosphate-based compound, the phosphate-based compound may be represented by Chemical Formula 1 below:

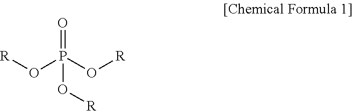

In Chemical Formula 1, three functional groups R are independent of one another (e.g., can be the same or different). Each R may independently be hydrogen or a functional group having 1 to 14 carbon atoms. In certain embodiments, each R may independently be hydrogen or a functional group having 1 to 12 carbon atoms, such as 1 to 9 carbon atoms or 1 to 6 carbon atoms.

In certain embodiments, at least one of the three R groups is not hydrogen. In other words, at least one R is a functional group having 1 to 14 carbon atoms.

In certain embodiments, each functional group is independently a hydrocarbyl group. As used herein, “hydrocarbyl” refers to a univalent organic radical containing carbon and hydrogen, formed by removing one hydrogen atom from a hydrocarbon, such as alkyl, alkenyl, alkynyl, and aryl radicals. From the viewpoint of chemical stability, the functional group may be an alkyl group. Each functional group may independently be linear, branched, cyclic, or any combination thereof. According to another embodiment, each R may be optionally substituted with a heteroatom. For example, each R may independently be substituted with one or more of O, N, S, P, B, F, Cl, Br, I, or any combination thereof. In certain embodiments, one or more R is independently substituted with one or more halogen atoms. For example, one or more R may independently be a halogen-substituted alkyl group. In certain embodiments, one or more R is independently substituted with one or more fluorine (F) atoms.

In certain embodiments, the total number of carbon atoms in the compound of Chemical Formula 1 may be 1 to 14. This means that one molecule having the structure of Chemical Formula 1 contains 1 to 14 carbon atoms. In certain embodiments, the total number of carbon atoms may be 1 to 12, 1 to 9, or 1 to 6.

As noted above, the second phosphorus-based additive of the present disclosure has a greater molecular weight than the first phosphorus-based additive. Accordingly, the molecular weight of the second phosphorus-based additive may be equal to or greater than about 100 g/mol. According to one embodiment, the molecular weight of the second phosphorus-based additive may be about 100 to about 500 g/mol, such as about 100 to about 400 g/mol, about 110 to about 500 g/mol, about 150 to about 400 g/mol, about 150 to about 300 g/mol, about 200 to about 500 g/mol, about 200 to about 400 g/mol, about 200 to about 300 g/mol, about 300 to about 500 g/mol, about 300 to about 400 g/mol, about 400 to about 500 g/mol, or about 400 to about 450 g/mol. If the molecular weight of the second phosphorus-based additive exceeds the aforementioned range, the decomposition temperature increases, which may cause a problem of reduced flame retardancy at approximately 400° C. According to another embodiment, the decomposition temperature of the second phosphorus-based additive may be about 120° C. to about 450° C., about 150° C. to about 450° C., about 150° C. to about 430° C., about 180° C. to about 430° C., about 180° C. to about 400° C., about 180° C. to about 250° C., about 200 to about 400° C., about 370° C. to about 430° C., or about 380° C. to about 420° C. When the ambient temperature reaches the decomposition temperature, the second phosphorus-based additive may undergo thermal decomposition and perform a flame-retardant function. When the molecular weight range of the first phosphorus-based additive overlaps with the molecular weight range of the second phosphorus-based additive, the phosphorus-based additive having a larger molecular weight may be classified as the second phosphorus-based additive. According to an embodiment, the difference in molecular weight between the first phosphorus-based additive and the second phosphorus-based additive may be at least 1 g/mol, at least 10 g/mol, at least 15 g/mol, or at least 20 g/mol.

The second phosphorus-based additive may include a phosphate-based compound. In certain embodiments, the phosphate-based compound may be an organic phosphate compound. According to one embodiment, the second phosphorus-based additive may be a phosphate-based compound. According to another embodiment, the second phosphorus-based additive may comprise at least one phosphate-based compound.

In embodiments in which the second phosphorus-based additive comprises a phosphate-based compound, the second phosphorus-based additive may comprise a compound represented by Chemical Formula 2 below:

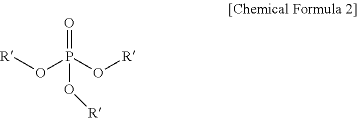

In Chemical Formula 2, three functional groups R′ are independent of one another. Each R′ may independently be hydrogen or a functional group having 1 to 30 carbon atoms. In certain embodiments, each R′ may be hydrogen or a functional group having 1 to 26 carbon atoms.

In certain embodiments, at least one of the three R′ groups is not hydrogen. In other words, at least one R′ is a functional group having 1 to 30 carbon atoms.

In certain embodiments, the functional group is a hydrocarbyl group. From the viewpoint of chemical stability, the functional group may be an alkyl group. The functional group may be linear, branched, cyclic, or any combination thereof. According to another embodiment, R′ may be optionally substituted with a heteroatom. For example, the R′ may be substituted with one or more of O, N, S, P, B, F, Cl, Br, I, or any combination thereof. In certain embodiments, R′ is substituted with one or more halogen atoms. In certain embodiments, R′ may be a halogen-substituted alkyl group. In certain embodiments, R′ is substituted with one or more fluorine (F) atoms.

In certain embodiment, the total number of carbon atoms in the phosphate-based compound of Chemical Formula 2 may be 4 to 30. In certain embodiments, the total number of carbon atoms may be 7 to 30, 10 to 30, or 12 to 30.

According to some embodiments, the selection of the second phosphorus-based additive may be informed by the selection of the first phosphorus-based additive, and vice versa. For example, in certain embodiments:
i) When one or more R in the first phosphorus-based additive is an alkyl group, one or more R′ in the second phosphorus-based additive may also be an alkyl group.
ii) When all R groups in the first phosphorus-based additive are alkyl groups, all R′ groups in the second phosphorus-based additive may also be alkyl groups.
iii) When all R groups in the first phosphorus-based additive are unsubstituted alkyl groups, all R′ groups in the second phosphorus-based additive may also be unsubstituted alkyl groups.
iv) When one or more R in the first phosphorus-based additive is a linear alkyl group, one or more R′ in the second phosphorus-based additive may be a branched alkyl group.
V) When all R groups in the first phosphorus-based additive are linear alkyl groups, all R′ groups in the second phosphorus-based additive may be branched alkyl groups.
vi) When all R groups in the first phosphorus-based additive are identical, all R′ groups in the second phosphorus-based additive may also be identical.
vii) When the total number of carbon atoms in the phosphate-based compound of the first phosphorus-based additive is 1 to 6, the total number of carbon atoms in the phosphate-based compound of the second phosphorus-based additive may be 7 to 30.

According to one embodiment, the first phosphorus-based additive and the second phosphorus-based additive satisfy at least one of the above-described conditions i) to vii). In certain embodiments, the phosphorus-based additives may satisfy at least two, and further embodiments, at least three, of the above-described conditions i) to vii).

In the phosphorus-based additive composition, the first phosphorus-based additive and the second phosphorus-based additive may be uniformly mixed in an appropriate ratio. According to one embodiment, the weight ratio of the first phosphorus-based additive to the second phosphorus-based additive in the phosphorus-based additive composition may be about 1:3 to about 3:1. Without wishing to be bound by theory, when the weight ratio of the first phosphorus-based additive to the second phosphorus-based additive in the phosphorus-based additive composition exceeds the above-described range, the flame-retardant effect at a specific ambient temperature may be reduced.

Use of the phosphorus-based additive composition in a thermal management fluid may also increase the flash point of a fluid to which it is added, e.g., a thermal management fluid. While not wishing to be bound by any particular theory, it is believed that during use of the thermal management fluid, radicals generated from the decomposition of volatilized gaseous species may induce the formation of highly reactive radicals from the base oil. However, radicals generated through thermal decomposition of the additive are believed to scavenge such highly reactive radicals, thereby improving the flash point of the fluid.

According to one embodiment, the phosphorus-based additive composition may increase the flash point of the thermal management fluid by at least 10° C. (ΔFP≥10° C.). Here, the ΔFP is defined as: ΔFP=(flash point of a fluid containing the phosphorus-based additive composition)−(flash point of a fluid not containing the phosphorus-based additive composition). In the present disclosure, the flash point of the thermal management fluid is measured in accordance with ASTM D93. The ΔFP of the thermal management fluid is a value calculated when the phosphorus-based additive composition is added to the thermal management fluid at a weight of about 2 to about 10 wt % based on the total weight of the thermal management fluid composition. In certain embodiments, the phosphorus-based additive composition can increase the flash point of a thermal management fluid (ΔFP) by about 10 to about 100° C., by about 20 to about 90° C., by about 30 to about 80° C., or by about 40 to about 80° C.

The phosphorus-based additive composition described above may be incorporated into a conventional thermal management fluid and is expected to, when thermal runaway occurs in an electronic product including a battery module, more effectively suppress fire propagation to adjacent battery cells within the module, thereby providing safety improvements such as prevention of large-scale fires. Additionally, since the phosphorus-based additive composition improves the flash point of the thermal management fluid, base oils that were previously unsuitable for use in thermal management fluids due to low flash points may become usable. Accordingly, the phosphorus-based additive composition is expected to provide the effect of broadening the selection range of base oils for thermal management fluids.

### Thermal Management Fluid Composition

Another aspect of the present disclosure provides a thermal management fluid composition comprising the above-described phosphorus-based additives. Hereinafter, unless otherwise specified, the descriptions provided above with respect to the additives may be equally applicable, and redundant descriptions may be omitted.

The thermal management fluid composition disclosed herein comprises a base oil and a phosphorus-based additive (e.g., as described according to any embodiment disclosed herein). The thermal management fluid composition possesses physical properties such as excellent electrical insulation performance and cooling performance, enabling direct contact with an electronic product to cool the electronic product. Accordingly, according to one embodiment, such a thermal management fluid composition may be used for immersion cooling.

Regarding the base oil, any conventional or future base oil suitable for use as a thermal management fluid may be employed. That is, any oil compatible with both traditional, petroleum-refined base stocks (API Group I/II) and advanced, synthetic or next-generation base stocks (Group III/IV/V) may be used. For example, suitable base oils include mineral oil, synthetic oil, vegetable oil, or any combination thereof. As used herein, mineral oil refers to an oil derived (refined) from crude oil without undergoing a separate synthetic process. In the present disclosure, mineral oil may be or comprise base oils corresponding to American Petroleum Institute (API) Groups I to III. The synthetic oil may comprise polyalphaolefin (PAO), gas-to-liquid (GTL) base oil, coal-to-liquid (CTL) base oil, or ester-based oil.

In one embodiment, the thermal management fluid composition may comprise about 90 to about 98 wt % of the base oil and equal to or less than about 8 wt % of the phosphorus-based additive, based on the total weight of the thermal management fluid composition. In certain embodiments, the content of the base oil in the thermal management fluid composition may be about 92 to about 98 wt %. Without wishing to be bound by theory, when the content of the base oil exceeds about 98 wt %, the above-described additives may weaken in their intended functions. However, when the content of the base oil is less than about 90 wt %, the amount of additives, which are generally more expensive than the base oil, may increase, thereby leading to an increase in the final product cost.

As noted above, the content of the phosphorus-based additive in the thermal management fluid composition may be equal to or less than about 8 wt %. In certain embodiments, the content of the phosphorus-based additive in the thermal management fluid composition may be greater than 0 to equal to or less than about 8 wt %, about 2 to about 8 wt %, or about 2 to about 6 wt %. Without wishing to be bound by theory, when the phosphorus-based additive in the thermal management fluid composition is at least about 2 wt %, fire propagation suppression performance may be improved. However, when the content of the phosphorus-based additive in the thermal management fluid composition exceeds the above numerical range, the phosphorus-based additive may not be fully dissolved in the thermal management fluid composition and may remain in the form of droplets within the base oil. Such non-uniform dissolution of the phosphorus-based additive may cause a degradation in fire propagation prevention performance.

As noted above, the phosphorus-based additive may comprise a first phosphorus-based additive and a second phosphorus-based additive. In certain embodiments, the first phosphorus-based additive has a molecular weight of about 100 g/mol to less than about 300 g/mol. The second phosphorus-based additive may have a molecular weight of about 100 to about 500 g/mol. In some embodiments, the content of the first phosphorus-based additive in the thermal management fluid composition may be greater than 0 to equal to or less than about 4 wt %, such as about 1 to about 4 wt %, or about 1 to about 3 wt %. In some embodiments, the content of the second phosphorus-based additive in the thermal management fluid composition may be greater than 0 to equal to or less than 4 wt %, such as about 1 to about 4 wt %, or about 1 to about 3 wt %.

In any embodiment, the thermal management fluid composition may further comprise an additive other than and additional to the first and second phosphorus-based additive described herein. In the present disclosure, such an additional additive is referred to as a second additive in order to distinguish it from the phosphorus-based additive (first additive). The second additive is not particularly limited, provided that it is usable for improving the physical properties of the thermal management fluid composition. For example, the second additive may comprise an antioxidant, an anti-foaming agent, a corrosion inhibitor, a detergent, a dispersant, a friction modifier, an anti-wear agent, an extreme-pressure additive, a viscosity index improver, a pour-point depressant, a viscosity modifier, or any combination thereof.

The content of the second additive in the thermal management fluid composition may be equal to or less than about 2 wt %. In certain embodiments, the content of the second additive in the thermal management fluid composition may be 0 to about 2 wt %, about 0.1 to about 2 wt %, or about 0.5 to about 2 wt %.

As described above, the flash point of the thermal management fluid composition may be improved (increased) by the addition of the aforementioned additives to the thermal management fluid. According to one embodiment, the flash point of the thermal management fluid composition (comprising the first and second phosphorus-based additives) may be at least about 200° C. In certain embodiments, the flash point of the thermal management fluid composition may be about 210° C. to about 300° C., about 220° C. to about 290° C., about 230° C. to about 280° C., or about 240° C. to about 280° C. In certain embodiments, the thermal management fluid composition may employ a base oil having a relatively low viscosity. In this case, the flash point of such a thermal management fluid composition may differ from the above-described range. In certain embodiments, the flash point of the thermal management fluid composition is not less than about 200° C.

Use of the thermal management fluid composition of the present disclosure, which comprises the additives described above, may reduce the likelihood of fire propagation during battery thermal runaway in an electronic product not only through physical fire suppression such as oxygen deprivation (smothering), but also through chemical fire suppression. Accordingly, when used as an immersion-cooling thermal management fluid, the thermal management fluid composition is expected to mitigate damage in the event of a battery fire.

Additional description of the embodiments of the present disclosure will be provided below with reference to specific experimental examples. However, the following examples and comparative examples included in the experimental examples are only given for illustrating the embodiments and do not limit the appended claims. It will be apparent to those skilled in the art that various modifications and alterations of the examples may be made without departing from the scope and spirit of the present disclosure. These modifications and alterations will fall within the appended claims.

### EXAMPLES

### 1. Preparation of Thermal Management Fluid Composition

A thermal management fluid composition was prepared by combining a base oil and phosphorus-based additives. As the base oil, YUBASE 3 was used, which has a flash point of about 184° C. measured according to ASTM D93, a kinematic viscosity at 40° C. of 12.4 cSt, and a kinematic viscosity at 100° C. of 3.1 cSt. As a first phosphorus-based additive, triethyl phosphate, having a molecular weight of 182 g/mol and a flash point of about 124° C. measured according to ASTM D93, was used. As a second phosphorus-based additive, tris(2-ethylhexyl) phosphate, having a molecular weight of 434 g/mol and a flash point of about 178° C. measured according to ASTM D93, was used.

The content of each compositional component in Examples 1 to 4 and Comparative Examples 1 to 3 is presented in Table 1 below.

TABLE 1

| | Base oil | Triethyl | Tris(2-ethylhexyl) |
|---|---|---|---|
| | (wt %) | phosphate (wt %) | phosphate (wt %) |
| Comparative Example 1 | 100 | — | — |
| Comparative Example 2 | 97.5 | 2.5 | — |
| Comparative Example 3 | 95.0 | — | 5.0 |
| Example 1 | 95.0 | 2.5 | 2.5 |
| Example 2 | 96.0 | 2.0 | 2.0 |
| Example 3 | 93.0 | 2.0 | 5.0 |
| Example 4 | 90.0 | 2.5 | 7.5 |

### 2. Performance Evaluation of Prepared Thermal Management Fluid Compositions

### (1) Flash Point Measurement

The flash point of each of the thermal management fluid compositions of the above Comparative Examples and Examples was measured and the results are presented in Table 2 below. The flash point measurement was performed in accordance with ASTM D93.

### (2) Battery Cell Fire Propagation Test

Four pouch cells were arranged in a test module by symmetrically stacking two cells on each side of a thermal insulation layer, after which the assembled module was fully immersed in each of the thermal management fluid compositions of Comparative Examples 1 and 2 and Examples 2 and 4. Subsequently, thermal runaway and explosion were intentionally induced in the outermost cell on one side, and the occurrence of fire propagation to the cell adjacent to the insulation layer on the opposite side, as well as the temperature behavior of the corresponding battery cell, were observed. The results are presented in Table 2 below. Cases in which fire propagation to the adjacent cell beyond the insulation layer did not occur were marked as “Success”, whereas cases in which fire propagation occurred were marked as “Failure”.

TABLE 2

| | Comparative | Comparative | Comparative | Example | Example | Example | Example |
|---|---|---|---|---|---|---|---|
| | Example 1 | Example 2 | Example 3 | 1 | 2 | 3 | 4 |
| Flash point | 184 | 214 | 184 | 230 | 230 | 258 | 258 |
| (° C.) | | | | | | | |
| Fire | Failure | Success | — | — | Success | — | Success |
| propagation | | | | | | | |
| Adjacent cell | 158 | 137 | — | — | 101 | — | 98 |
| temperature | | | | | | | |
| (° C.) | | | | | | | |

Referring to Table 2, it can be seen that the flash points of the Examples including the phosphorus-based additives of the present disclosure were significantly increased compared to those of the Comparative Examples. It can also be found that use of the phosphorus-based additives of the present disclosure in a thermal management fluid not only could prevent fire propagation beyond the insulation layer, but also effectively suppress heating of adjacent cells caused by the fire.

The phosphorus-based additives of the present disclosure may be readily applicable to conventional thermal management fluids and is expected to contribute to preventing battery thermal runaway and fire propagation, particularly when utilized in immersion cooling of electronic products such as electric vehicles including high-capacity batteries.

The foregoing description is merely an example of applying the principles of the present disclosure, and other configurations may be further included without departing from the scope of the present disclosure.

What is claimed is:

1. A phosphorus-based additive composition for a thermal management fluid, the phosphorus-based additive composition comprising:
a first phosphorus-based additive; and
a second phosphorus-based additive, wherein the second phosphorus-based additive has a greater molecular weight than the first phosphorus-based additive.

2. The phosphorus-based additive composition of claim 1, wherein the first phosphorus-based additive has a molecular weight of about 100 g/mol to less than about 300 g/mol.

3. The phosphorus-based additive composition of claim 1, wherein the first phosphorus-based additive comprises a compound represented by Chemical Formula 1 below: 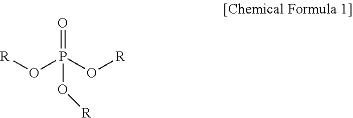
wherein each R is independently hydrogen or a functional group having 1 to 14 carbon atoms,
at least one R is not hydrogen, and
a total number of carbon atoms in the compound is 1 to 14.

4. The phosphorus-based additive composition of claim 3, wherein each functional group is independently a hydrocarbyl group.

5. The phosphorus-based additive composition of claim 1, wherein the second phosphorus-based additive has a molecular weight of about 100 g/mol to about 500 g/mol.

6. The phosphorus-based additive composition of claim 1, wherein the second phosphorus-based additive comprises a compound represented by Chemical Formula 2 below: 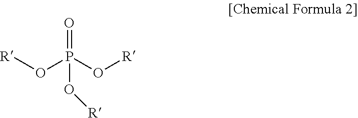
wherein each R′ is independently hydrogen or a functional group having 1 to 30 carbon atoms,
at least one R′ is not hydrogen, and
a total number of carbon atoms in the compound is 1 to 30.

7. The phosphorus-based additive composition of claim 6, wherein each functional group is independently a hydrocarbyl group.

8. The phosphorus-based additive composition of claim 1, wherein a weight ratio of the first phosphorus-based additive to the second phosphorus-based additive is about 1:3 to about 3:1.

9. The phosphorus-based additive composition of claim 1, wherein adding the phosphorus-based additive composition to a thermal management fluid increases a flash point of the thermal management fluid by at least 10° C.

10. A thermal management fluid composition, comprising:
a base oil; and
a phosphorus-based additive.

11. The thermal management fluid composition of claim 10, comprising:
about 90 wt % to about 98 wt % of the base oil; and
equal to or less than about 8 wt % of the phosphorus-based additive.

12. The thermal management fluid composition of claim 10, wherein the base oil comprises mineral oil, synthetic oil, vegetable oil, or any combination thereof.

13. The thermal management fluid composition of claim 10, wherein the phosphorus-based additive comprises:
a first phosphorus-based additive having a molecular weight of about 100 g/mol to less than about 300 g/mol; and
a second phosphorus-based additive having a molecular weight of about 100 g/mol to about 500 g/mol.

14. The thermal management fluid composition of claim 10, further comprising:
a second additive,
wherein the second additive comprises an antioxidant, an anti-foaming agent, a corrosion inhibitor, a detergent, a dispersant, a friction modifier, an anti-wear agent, an extreme-pressure additive, a viscosity index improver, a pour-point depressant, a viscosity modifier, or any combination thereof.

15. The thermal management fluid composition of claim 10, wherein the thermal management fluid composition has a flash point of at least about 200° C.

16. The thermal management fluid composition of claim 13, wherein the first phosphorus-based additive comprises triethyl phosphate.

17. The thermal management fluid composition of claim 13, wherein the second phosphorus-based additive comprises tris(2-ethylhexyl) phosphate.

18. A method of improving fire propagation prevention in a thermal management fluid, comprising adding the phosphorus-based additive composition of claim 1 to the thermal management fluid.

19. A method of immersion cooling an electronic device, comprising contacting the device with the thermal management fluid composition of claim 10.

20. A method of increasing the flash point of a thermal management fluid by at least about 10° C., comprising adding the phosphorus-based additive composition of claim 1 to the thermal management fluid.
